(19) United States
(12) Patent Application Publication
(10) Pub. No.: US 2013/0106443 A1
(43) Pub. Date: May 2, 2013

(54) SENSOR HAVING A TRANSISTOR AND IMPRINT SITES

(71) Applicants: Warren Jackson, San Francisco, CA (US); Devin Alexander Mourey, Corvallis, OR (US)

(72) Inventors: Warren Jackson, San Francisco, CA (US); Devin Alexander Mourey, Corvallis, OR (US)

(21) Appl. No.: 13/285,828

(22) Filed: Oct. 31, 2011

(51) Int. Cl. G01R 27/26; H01L 21/336; G01R 27/08; H01L 29/66

(52) U.S. Cl. 324/679; 257/253; 438/49; 324/693; 257/E29.166; 257/E21.409

(57) ABSTRACT

A sensor includes a transistor and a receptor layer positioned on the transistor. The receptor layer comprises a plurality of imprint sites, wherein each of the plurality of imprint sites is to mate with a portion of a target molecular species, and wherein at least two of the plurality of imprint sites are to mate with different portions of the target molecular species.

### BACKGROUND

Sensors that indicate the presence or absence of target species are widely used for many different purposes. In order to be effective, the sensors should be both sensitive and selective. More particularly, the sensors should be sensitive to target species to be able to detect small quantities of the target species in order to avoid false negatives. In addition, the sensors should be selectively sensitive to the target species to avoid false positives from some confounding species being present.

Typical sensors include a detection or receptor element and signal transduction elements. The receptor element typically interacts with the target species, for instance, by physical absorption or physiorption, chemisorption, and microencapsulation. The transduction elements convert a change at the receptor surface into a measurable electrical signal. One type of conventional sensor is a field effect transistor (FET) based sensor. In these types of sensors, the metal gate of the FET based sensor is either replaced or coated with a sensitive thin film, insulator, or membrane, which operates as the receptor element. The FET based sensor operates on the general principal of detecting shifts in localized electric potential due to interactions at the receptor element. More particularly, the FET based sensor transduces a detection event into an electrical signal by way of change in the conductance of the channel region leading to a change in the drain current. The FET based sensor is operated as a sensor either by biasing the sensor with constant gate voltage and measuring the change in the current or by detecting the change in gate voltage required to maintain a constant current.

### BRIEF DESCRIPTION OF THE DRAWINGS

Features of the present disclosure are illustrated by way of example and not limited in the following figure(s), in which like numerals indicate like elements, in which:

FIGS. 1A and 1B, respectively, show cross-sectional side views of sensors, according to two examples of the present disclosure;

FIG. 1C shows a schematic top view of portions of the sensor depicted in FIG. 1B, according to an example of the present disclosure;

FIG. 1D shows a cross-sectional side view of a sensor and a device, according to an example of the present disclosure;

FIG. 1E shows respective diagrams applicable to the sensor and device depicted in FIG. 1D, according to an example of the present disclosure;

FIGS. 2A and 2B, respectively, show diagrams of sensor apparatuses, according to two examples of the present disclosure;

FIG. 3 shows a flow diagram of a method for fabricating the sensors depicted in one of FIGS. 1A and 1B, according to an example of the present disclosure; and

FIG. 4 shows a flow diagram of a method of implementing a sensor depicted in one of FIGS. 1A and 1B, according to an example of the present disclosure.

### DETAILED DESCRIPTION

For simplicity and illustrative purposes, the present disclosure is described by referring mainly to an example thereof. In the following description, numerous specific details are set forth in order to provide a thorough understanding of the present disclosure. It will be readily apparent however, that the present disclosure may be practiced without limitation to these specific details. In other instances, some methods and structures have not been described in detail so as not to unnecessarily obscure the present disclosure.

Disclosed herein are sensors, sensor apparatuses, a method of fabricating the sensors, and a method of implementing the sensors. The sensors include a transistor and a receptor layer. A plurality of imprint sites to selectively mate with a portion of at least one species are formed into the receptor layer. According to an example, the imprint sites are formed into the receptor layer through the use of template molecules, which may comprise the target molecules, and functional monomers. Thus, for instance, a first imprint site is at least one of shaped and chemically active to mate with a first portion of a target species and a second imprint site is at least one of shaped and chemically active to mate with a different portion of the target species. As the target species comprise three dimensional structures, different portions of the target species may contact the receptor layer. In addition, confounding species contained in a sample may be able to mate with one of the imprint sites, but it is unlikely that the confounding species will be able to mate with all of the imprint sites.

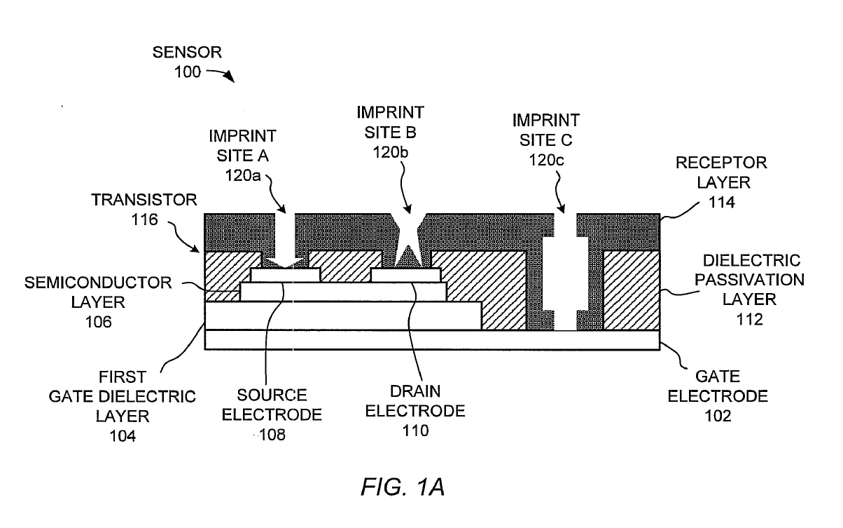

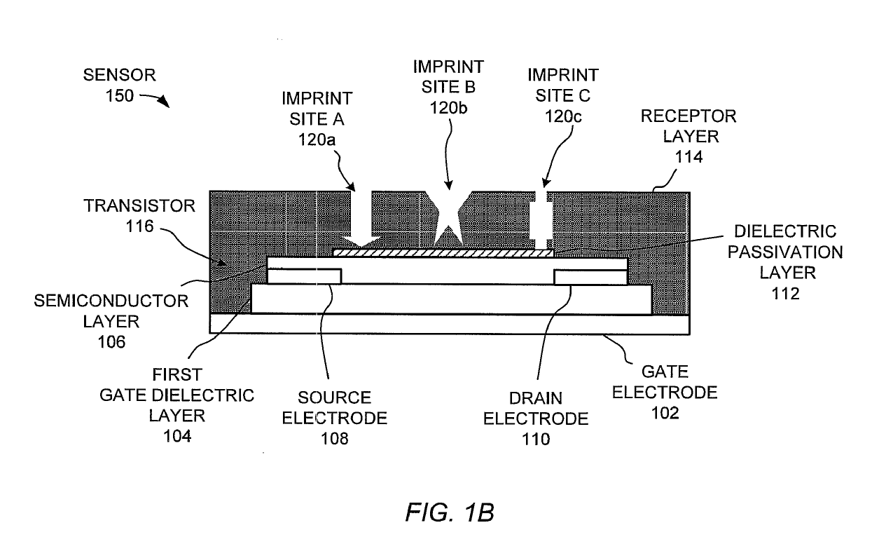

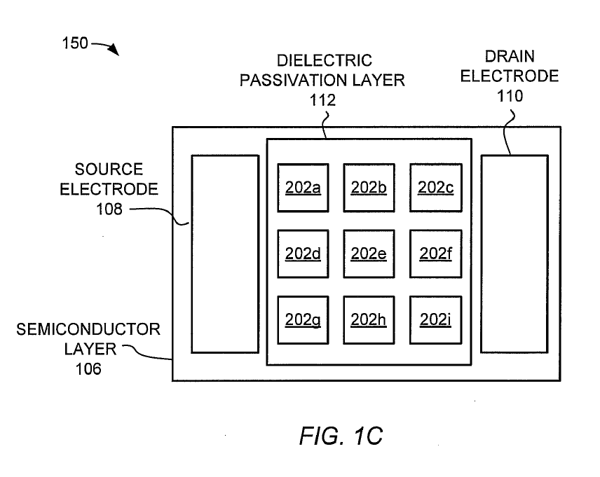

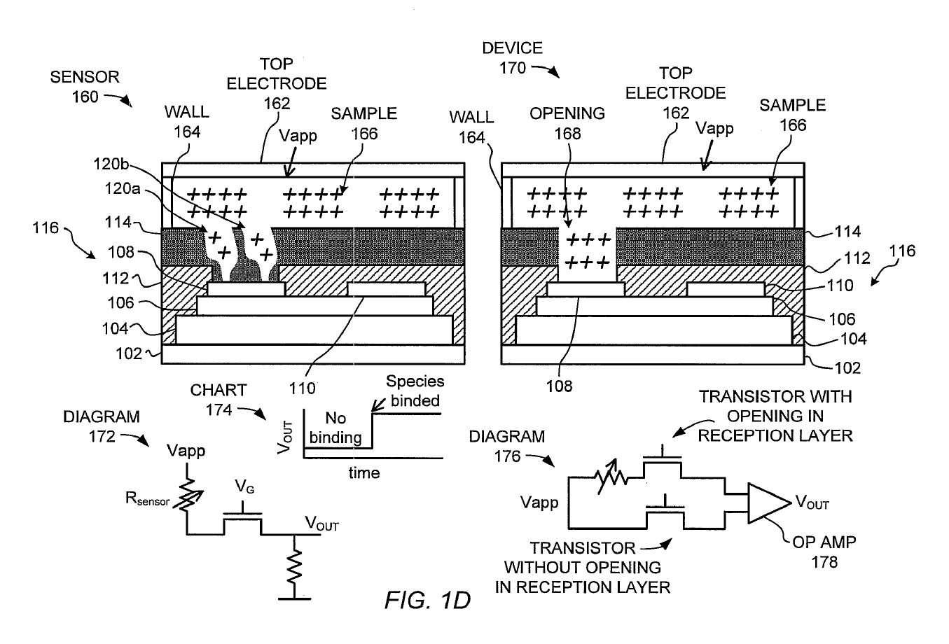

According to various examples disclosed herein, the imprint sites are selectively positioned in the receptor layer over various sections of the transistor. In one example, the imprint sites are positioned directly over two of a source electrode, and drain electrode, and a gate electrode. In another example, the imprint sites are positioned over a dielectric passivation layer. The placement of the imprint sites generally results in improved selectivity by providing cross sensitivity through an AND function. In one example, the transistor conductance may change substantially only if all available imprint sites are filled. In this case, a specific combination of species needs to be present to change the transistor conductance or the conductance to the channel. Similarly, the conductance from the drain also changes if all the sites are occupied, for instance, as described below with respect to the example depicted in FIG. 1D. Thus, in one example, a large conductance results only when there are concurrently open sites for both the source and drain sites. This additive approach is referred herein as an AND function. In another example, the conductance to the source and drain or the transistor conductance may be sensitive to each different imprint site in a specific way and the conductance may be constructed so that conductance is large if open sites exist for any of the template species. This approach is referred herein as an OR function. In both cases, more information and resulting sensitivity are extracted as compared with conventional single transistor sensors.

Through implementation of the sensors and methods disclosed herein, molecular species may selectively be captured in the imprint sites, which may also hold the molecules for extended detection of current applied across the sensor. In addition, the use of a transistor in the sensor generally enables relatively small currents to be detected and therefore, the sensors and methods disclosed herein enable detection of relatively small amounts of the target species. The sensors and methods disclosed herein generally enable combinatorial and logical conjunction of various molecular species, thereby resulting in species selectivity and sensitivity in the presence of many confounding species.

In other examples, a plurality of the sensors are arranged on a substrate to detect the same or different species. In addition, the use of multiple sensors generally increases the probability that target species will be captured by the imprint sites, thus leading to more accurate detection results.

FIGS. 1A and 1B, respectively, show cross-sectional side views of sensors 100, 150, according to two examples of the present disclosure. As shown in FIGS. 1A and 1B, each of the sensors 100, 150 comprises a gate electrode 102, a first gate dielectric layer 104, a semiconductor layer 106, a source electrode 108, a drain electrode 110, a dielectric passivation layer 112, which collectively form a transistor 116. The gate electrode 102, the source electrode 108, and the drain electrode 110 are collectively referenced herein as terminals. The sensors 100, 150 also include a receptor layer 114 and a plurality of imprint sites 120a-120c. The plurality of imprint sites 120a-120c are formed in the receptor layer 114.

It should be clearly understood that the sensors 100, 150 depicted in FIGS. 1A and 1B may include additional elements and that some of the elements described herein may be removed and/or modified without departing from scopes of the sensors 100, 150. Thus, for instance, although the sensors 100, 150 have each been depicted as including three imprint sites 120a-120c, the sensors 100, 150 may include any reasonable number of imprint sites 100, 150 without departing from scopes of the sensors 100, 150. In addition, although additional electrical connections have not been shown in FIGS. 1A and 1B, it should be understood that the additional electrical connections are to be made to the sensors 100, 150 to enable various measurements to be made on the sensors 100, 150. It should also be understood that the elements depicted in FIGS. 1A and 1B are not drawn to scale and thus, the elements may have different relative sizes with respect to each other than as shown therein.

Generally speaking, the sensors 100, 150 comprise field-effect transistors that are to be implemented in the detection of biological and/or chemical species. In operation, channel conductances of the sensors 100, 150 when a species has mated with at least one of the plurality of imprint sites 120a-120c differs from when the imprint sites 120a-120c remain empty. This occurs because when the species, such as, a particular type of molecule, has an electrical charge, the electrical charge varies the channel conductances of the sensors 100, 150. In addition, because the sensors 100, 150 comprise transistors 116, the sensors 100, 150 are able to provide gain, i.e., a small change in gate charge can result in a much larger charge in the source drain current or charge. The difference in the channel conductance of the sensors 100, 150 is able to be measured to determine whether a target species is present in or likely absent from a sample introduced onto the sensor 100, 150.

The imprint sites 120a-120c are depicted as having various shapes for purposes of illustration. As such, the various shapes of the imprint sites 120a-120c in FIGS. 1A and 1B are to be construed as representative shapes and not the actual shapes of the species to mate with the imprint sites 120a-120c. Instead, the imprint sites 120a-120c are at least one of shaped and chemically active to match the target molecular species that is to be detected. Thus, unless a portion of the species has the appropriate shape or chemically active sites to mate with one of the imprint sites 120a-120c, when a sample is introduced onto the sensors 100,150, the species contained in the sample will pass over the sensor 100, 150 and thus will not mate with one of the imprint sites 120a-120c. The channel conductance through the sensors 100, 150 will therefore remain unchanged from prior to introduction of the sample.

However, if the sample contains species having the appropriate shape or chemically active sites to mate with at least one of the imprint sites 120a-120c, the species is likely to mate with at least one of the imprint sites 120a-120c when the sample is introduced onto the sensors 100, 150. In addition, the species is likely to be held or otherwise trapped into at least one of the imprint sites 120a-120c. Thus, when a current is applied across the sensor 100, 150, a measurable change in the channel conductance is likely to be detected from a channel conductance measured prior to the introduction of the sample when a species having charge has mated with at least one imprint site 120a-120c. As discussed in greater detail herein below with the sensor 160 depicted in FIG. 1D, a measurable change in the channel conductance may be detected even with species that do not have a charge.

According to an example, the imprint sites 120a-120c are formed through implementation of a molecular imprinting operation. As is generally known with molecular imprinting operations, a template molecule, functional monomers, a crosslinker, an initiator, a porogenic solvent, and extraction solvent are used to form the imprint sites 120a-120c. The template molecule may be reacted with the functional monomers before being embedded within the receptor layer 114, for instance, such that the functional monomers become attached at various locations of the template molecule. In addition, the template molecules may be removed from the receptor layer 114, while the functional monomers remain in the imprint sites 120a-120c formed by the template molecules. If the target molecule was reacted with the functional monomer, an extraction solvent is used to separate the target molecules from the functional monomers leaving the functional monomers embedded within the receptor layer 114 with functional sites used to discriminate various target molecules based on chemical functionality as well as shape. The template molecules may be embedded into the receptor layer 114 in any suitable manner. For instance, the receptor layer 114 comprises a polymer material and the template molecules are mixed with the polymer material following polymerization of the polymer material. Examples of suitable polymer materials include UV-curable or thermal curable imprinting resist, polyalkylacrylate, polysiloxane, polydimethylsiloxane (PDMS) elastomer, polyimide, polyethylene, polypropelene, fluoropolymer, etc., or any combination thereof. Additional examples of suitable polymer materials include hydrophilic polymer networks, which may be particularly useful for detection of water soluble target molecules.

By way of particular example, a composition of the template molecules, the functional monomers, crosslinker, initiator, porogenic solvent, extraction solvent, and the polymer material is supplied into an inkjet-type dispensing mechanism, such as, a piezoelectric inkjet mechanism, a thermoelectric inkjet mechanism, etc., although other mechanisms may be implemented to deposit the composition. In this example, the inkjet-type dispensing mechanism is implemented to deposit the composition onto a transistor 116.

As shown in FIG. 1A, the imprint sites 120a-120c are depicted as being respectively positioned over the source electrode 108, the drain electrode 110, and a section of the gate electrode 102 that directly contacts the receptor layer 114. According to an example, instead of being positioned directly over each of the source electrode 108, the drain electrode 110, and a section of the gate electrode 102 that directly contacts the receptor layer 114, different combinations of imprint site 120a-120c usage are possible. For instance, any one of the imprint sites 120a-120c may be omitted. In one regard, the use of multiple imprint sites 120a-120c in the sensor 100 over the different terminals of the sensor 100 is to result in improved selectivity by providing the AND function.

In addition, if imprint sites 120a-120c are provided over each of the gate electrode 102, the source electrode 108, and the drain electrode 110 as shown in FIG. 1A, the differential response may be utilized to provide more effective sensitivity and/or selectivity for a single transistor sensor. For example, the imprint sites 120a-120c over the source electrode 108 and drain electrode 110 may act to modulate the series resistance for the electrode, which will add linearly with the transistor resistance, while the imprint sites 120a-120c over the gate electrode 102 will result in a threshold voltage shift, which will result in a non-linear change in conductance. These changes may be viewed as additive or subtractive depending on the application and may result in larger effective sensitivity and/or selectivity.

According to an example, the composition containing the template molecules, polymer material, and functional monomers is deposited over the terminals and another composition, for instance, that does not contain the template molecules is deposited over the remaining areas of the sensor 100. In this example, the composition containing the template molecules is deposited onto at least two of the terminals. According to another example, different compositions containing different types of template molecules are deposited onto different ones of the terminals. Thus, for instance, the different compositions may be supplied into different inkjet-type dispensing mechanisms, and the different inkjet-type dispensing mechanisms may be implemented to deposit the different compositions onto the different terminals of the sensor 100.

In another example, the composition containing the template molecules, the polymer material, and functional monomers is deposited over substantially the entire surface of the sensor, such that the template molecules are positioned over larger sections of the sensor 100. In any regard, chemical and/or mechanical processes may be performed on the top of the receptor layer 114 to expose at least some of the template molecules and to remove the exposed template molecules.

Various manners in which the sensor 100 is fabricated may result in at least some of the imprint sites 120a-120c failing to extend from a top of the receptor layer 114 to the terminals. As such, a portion of the receptor layer 114 may remain between bottoms of the imprint sites 120-120c and the terminals, without departing from the scope of the sensor 100.

As shown in FIG. 1B, the imprint sites 120a-120c are depicted as being positioned over the dielectric passivation layer 112. According to an example, the composition containing the template molecules, the polymer material, and functional monomers is deposited over the dielectric passivation layer 112 and another composition, for instance, that does not contain the template molecules is deposited over the remaining areas of the sensor 150. In this example, the composition containing the template molecules is deposited over particular sections of the dielectric passivation layer 112. The composition containing the template molecules is deposited in any suitable arrangement, for instance, along a line, diagonally, in an array, randomly, etc.

According to another example, different compositions containing different template molecules (and in certain instances, different functional monomers) are deposited onto different portions of the dielectric passivation layer 112, to thereby vary the types of molecules that are to mate with the imprint sites 120a-120c. Thus, for instance, the different compositions may be supplied into different inkjet-type dispensing mechanisms, and the different inkjet-type dispensing mechanisms may be implemented to deposit the different compositions onto different sections of the sensor 150. In this example, the different compositions may be deposited in any suitable arrangement, for instance, along a line, diagonally, in an array, randomly, etc.

In another example, the composition containing the template molecules, the polymer material, and the functional monomers is deposited over substantially the entire surface of the sensor 150, such that the template molecules are positioned over larger sections of the sensor 150. In any regard, chemical and/or mechanical processes may be performed on the top of the receptor layer 114 to expose at least some of the template molecules and to remove the exposed template molecules.

Various manners in which the sensor 150 is fabricated may result in at least some of the imprint sites 120a-120c failing to extend from a top of the receptor layer 114 to the dielectric passivation layer 112. As such, a portion of the receptor layer 114 may remain between bottoms of the imprint sites 120-120c and the dielectric passivation layer 112, without departing from the scope of the sensor 150.

Turning now to FIG. 1C, there is shown a schematic top view of portions of the sensor 150 depicted in FIG. 1B, according to an example of the present disclosure. The semiconductor layer 106, the source electrode 108, the drain electrode 110, and the dielectric passivation layer 112 are depicted in FIG. 1C. Additionally, multiple imprint sites 202a-202i are formed in an array in the receptor layer 114 (not shown). According to an example, each of the imprint sites 202a-202i is shaped to mate with a different target species. In this regard, and as discussed above, different compositions of polymer material and template molecules (as well as functional monomers) are deposited onto the various locations of the imprint sites 202a-202i. In addition, the template molecules are removed to form the various imprint sites 202a-202i.

In the configuration depicted in FIG. 1C, the current for the imprint sites 202a-202i along the channel is logically ANDed and the current across the channel is logically ORed. The placement of the imprint sites 202a-202i generally results in improved selectivity by providing cross sensitivity through an AND function. In one example, the transistor conductance through the sensor 150 may change substantially only if all available imprint sites 202a-202i are filled. In this case, multiple imprints would require that a specific combination of species be present to change the conductance. This additive approach is referred herein as an AND function. In another example, the transistor conductance through the sensor 150 may be sensitive to each different imprint 202a-202i in a specific way and the conductance may then be utilized to describe the species. This approach is referred herein as an OR function.

Turning now to FIG. 1D, there are shown cross-sectional side views of a sensor 160 and a device 170, according to an example of the present disclosure. As shown therein, the sensor 160 and the device 170 each includes the transistor 116 and the receptor layer 114 discussed above with respect to FIGS. 1A-1C. The transistors 116 in each of the sensor 160 and device 170 also include a gate electrode 102, a first gate dielectric layer 104, a semiconductor layer 106, a source electrode 108, a drain electrode 110, and a dielectric passivation layer 112, as also discussed above. In addition, the sensor 160 and the device 170 are also depicted as each including a top electrode 162 spaced from the receptor layer 114 by respective walls 164 to form a gap therebetween, through which a sample 166 is to be supplied.

As also shown in FIG. 1D, the receptor layer 114 of the sensor 160 includes imprint sites 120a,120b, which may be formed into the receptor layer 114 in any of the manners discussed above with respect to the imprint sites 120a,120b in the sensors 100, 150. As such, if the sample 166 contains species having the appropriate shape or chemically active sites to mate with at least one of the imprint sites, 120a, 120b, the species is likely to mate with at least one of the imprint sites 120a-120c. On the other hand, if the sample 166 does not contain species having the appropriate shape or chemically active sites to mate with at least one of the imprint sites, 120a, 120b, the imprint sites 120a, 120b are likely to remain empty. Although the imprint sites 120a, 120b have been depicted as being formed over the source electrode 108, it should be clearly understood that the imprint sites 120a, 120b may in addition, or alternatively, be formed over the drain electrode 110.

The receptor layer 114 of the device 170 includes a relatively large opening 168 that has been depicted as extending to the source electrode 110. In this regard, when the sample 166 is supplied into the gap between the receptor layer 114 and the top electrode 162, some portion of the sample 166 is to enter into the opening 168. Although the opening 168 has been depicted as being formed over the source electrode 108, it should be clearly understood that the opening 168 may in addition, or alternatively, be formed over the drain electrode 110.

As further shown in FIG. 1D, in each of the sensor 160 and the device 170, a voltage (Vapp) is to be applied from the top electrode 162, through the sample 166 and the receptor layer 114, and into the transistor 116. As shown in the diagram 172, the resistance through the sensor 160 is variable depending upon whether species have mated with the imprint sites 120a, 120b. For instance, in the chart 174, the output voltage (Vout) of the transistor 116 changes over time depending upon whether a species has mated with most or all of both of the imprint sites 120a, 120b. That is, the chart 174 shows that the output voltage (Vout) is substantially higher when the species has binded with most or all of sites 120a AND 120b.

Likewise, the diagram 176 shows the sources 160, 170 of two transistors, one source (sensor 160) with a receptor layer and the other source (device 170) with just an opening 168. The current passing through the receptor layer 114 and through the transistor 116 in the source (sensor 160) is compared to the current passing through opening 168. Any common signal affecting both the sensor 160 and the device 170 is subtracted in the op amp electronics 178 depicted in the diagram 176. The changes due to the receptor layer, on the other hand, just occur in the receptor layer 114 in the sensor 160 and is not subtracted out. One may also have a sensor 160 that is in contact with a solution with the target molecules and another sensor 160 which is in contact with the fluid without the target molecules. The signal difference out of the op amp in the diagram 176 would have the common signal removed and the difference would only reflect the changes in conductance due to molecules residing in the imprint sites 120a, 120b.

In the sensor 160, the presence of a species at most or all of the imprint sites 120a, 120b and the opening 168 gates the current to the transistor and results in a large reduction in the current flowing through the transistor and in the voltage (Vout). Hence, the signal reduction represents the presence of species attaching to the imprint sites 120a AND 120b AND with other species with imprint sites 120, 120b over the channels AND with imprint sites in series with the drain. The imprint sites in series with source or drain in the sensor 160 may also be in side by side sensors 160 with imprint sites 120a and 120b respectively. The current through the transistor is the sum of the currents through the two side by side portions. Thus a reduction in current occurs if either species 120a OR 120b is present. The same holds for sites in series with the drain.

Turning now to FIG. 1E, there are shown respective diagrams 176, 180, 190 applicable to the sensor 160 and device 170 depicted in FIG. 1D, according to an example of the present disclosure. As shown first in the diagram 180, a charging voltage (Vcharge) is depicted as being applied onto the sensor 160, for instance, by the top electrode 162. In other words a charging current (I_{charge}) is applied across the transistor 116. In this example, the transistor 116 is operable as a hold capacitor that discharges the charge over time. In the diagram 180, therefore, during a cycle A, the hold capacitor is charged and during a cycle B, the hold capacitor is discharged. The discharge rate of the hold capacitor is measured to determine whether the target species has binded to at least one of the imprint sites 120a, 120b. As shown in the diagram 190, the discharge rate of the hold capacitor may be lower when a target species has binded with at least one of the imprint sites 120a, 120b as compared with the discharge rate when a target species has not binded with at least one of the imprint sites 120a, 120b. As such, for large arrays of such sensors 160 and devices 170, the signal may be matrix addressed from the periphery of the array, thereby greatly reducing the number expensive contacts required to communicate signals outside of the sensors 160 and devices 170.

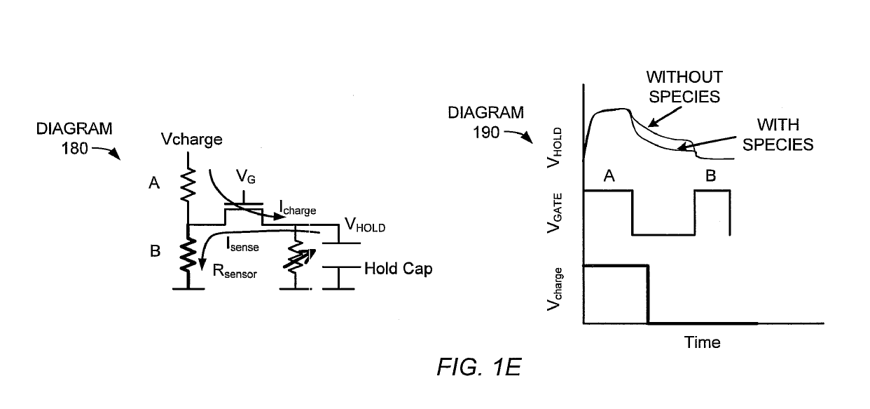

Turning now to FIGS. 2A and 2B, there are shown diagrams of sensor apparatuses 200, 250 that include a plurality of the sensors depicted in at least one of FIGS. 1A-1D, according to two examples. As shown in FIG. 2A, the sensor apparatus 200 includes a substrate 202 and a plurality of sensors 210a-210n. The sensors 210a-210n are depicted as being arranged in an array on a substrate 202. According to an example, the sensors 210a-210n are fabricated to detect the same type of species. In another example, at least some of the sensors 210a-210n are fabricated to detect species that are different from at least some of the other sensors 210-210n.

In any regard, the sensors 210a-210n are matrix addressable. In other words, various electronic circuitry may be provided in the substrate 202 and into each of the sensors 210a-210n to enable each of the sensors 210a-210n to be individually addressed. In this regard, the channel conductances of each of the sensors 210a-210n may individually be detected to determine whether the sensors 210a-210n have collected target species.

As shown in FIG. 2B, the sensor apparatus 250 includes a flexible substrate 252 that has been positioned into a rolled configuration and includes spacers 260 to maintain separation between sections of the flexible substrate 252. According to an example, the sensor apparatus 250 comprises the sensor apparatus 200. In this regard, a plurality of sensors 210a-210n are provided on the flexible substrate 252. As such, the sensor apparatus 250 enables a relatively large number of sensors 210a-210n to be positioned in a relatively small amount of space to receive a sample fluid flow 270. In one regard, the sensor apparatuses 200, 250 employ a large number of sensors 210a-210n to thereby enable a relatively more accurate determination to be made as to whether at least one target species is present in a tested sample.

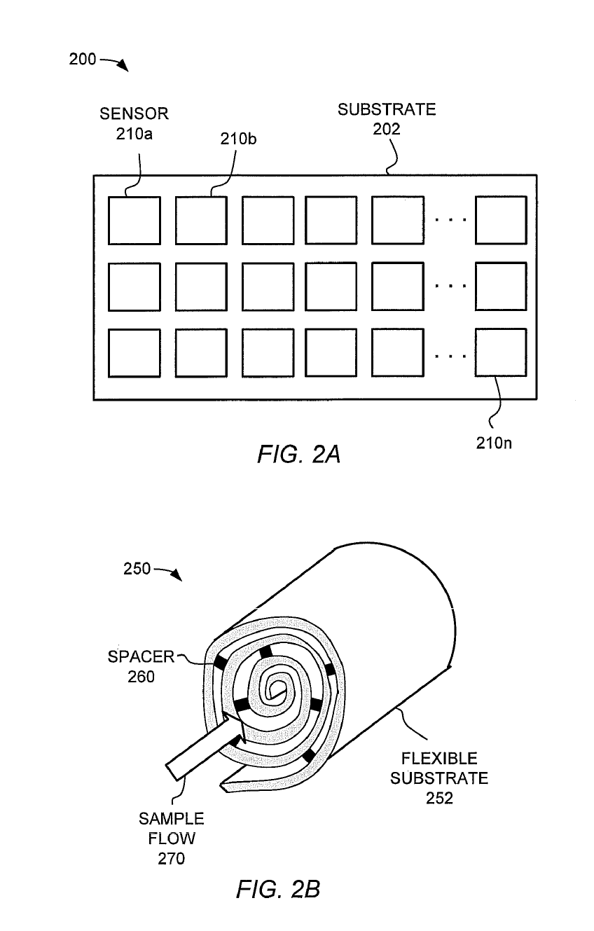

With reference now to FIG. 3, there is shown a method 300 of fabricating a sensor, for instance, the sensors 100, 150, depicted in FIGS. 1A. 1B. and 1D, according to an example of the present disclosure. It should be understood that the method 300 may include additional processes and that some of the processes described herein may be removed and/or modified without departing from a scope of the method 300.

At block 302, a transistor 116 is formed through imprint lithography or other suitable process onto a substrate. According to an example, the transistor 116 is formed on a flexible substrate to enable the transistor to be formed on a sensor apparatus 250 that is to be rolled up, for instance, as shown in FIG. 2B.

At block 304, at least one composition of a polymer material, template molecules, and functional monomers is formed on the transistor 116 to form a receptor layer 114. According to an example, the at least one composition is pre-mixed and a dispensing mechanism (not shown), such as, an inkjet-type dispensing mechanism, dispenses the at least one composition onto the transistor 116. In this example, the dispensing mechanism is implemented to deposit the at least one composition at desired locations on the transistor 116. With reference to FIG. 1A, the dispensing mechanism is implemented to deposit the composition onto sections above at least two of the gate electrode 102, the source electrode 108, and the drain electrode 110. With reference to FIG. 1B, the dispensing mechanism is implemented to deposit the composition onto a section of the transistor 116 above the dielectric passivation layer 112. Alternatively, the dispensing mechanism is implemented to deposit the at least one composition over substantially the entire surface of the transistor 116 in either of FIGS. 1A and 1B.

As also discussed above, and according to another example, a plurality of compositions containing different types of template molecules are deposited onto different sections of the transistor 116. In this example, the compositions containing the different types of template molecules may be deposited in an array, for instance, as depicted in FIG. 1C.

In other examples, the polymer material and the template molecules with the functional monomers are deposited separately onto the transistor 116 by separate dispensing mechanisms. Thus, for instance, a first inkjet-type dispensing mechanism is implemented to deposit the polymer material and a second inkjet-type dispensing mechanism is implemented to deposit the template molecules and functional monomers. In further examples, the polymer material and the template molecules (with the functional monomers) are deposited either separately or in combination onto the transistor 116 through other types of solution and non-solution dispensing operations, such as, spin coating, dip coating, physical vapor deposition (PVD), chemical vapor deposition (CVD), sputtering, etc. In these examples, the template molecules and functional monomers are deposited at desired locations with respect to the transistor 116 as the polymer material is deposited, for instance, as shown in FIGS. 1A and 1B. In each of these examples, functional monomers may be attached to the target molecules to create the templates for forming the imprint sites 120a-120c, 202a-202i.

At block 306, imprint sites 120a-120c, 202a-202i are formed in the receptor layer 114. The imprint sites 120a-120c, 202a-202i are formed through, for instance, chemical and/or mechanical processes performed on the receptor layer 114 to reveal the template molecules interspersed in the polymer material. By way of example, a chemical etching and/or laser ablation operation is performed to planarize the receptor layer 114. In addition, the revealed template molecules are removed from the polymer material through performance of chemical and/or mechanical processes. Thus, for instance, a chemical composition that is to dissolve the template molecules may be introduced onto the template molecules. As another example, a chemical composition containing elements that are to have a relatively strong bond to the template molecules may be introduced onto the template molecules to pull the template molecules out of the imprint sites 120a-120c, 202a-202i.

Once the template molecules have been removed, a sensor having a configuration, such as the sensors 100, 150, 160 depicted in FIGS. 1A, 1B, and 1D, is fabricated. In addition, the method 300 may be repeated or concurrently performed at a number of locations on a substrate 202 to form a plurality of sensors 100, 150, 160 as discussed above with respect to FIG. 2A. Moreover, the substrate 202 may comprise a flexible material, such as, a polymer material, and may be rolled into the configuration depicted in FIG. 2B.

Although not shown in FIG. 3, the method 300 may also include the addition of a top electrode 162 as shown in FIG. 1D. More particularly, the top electrode 162 may be positioned in a spaced arrangement with respect to the receptor layer 114 as shown therein.

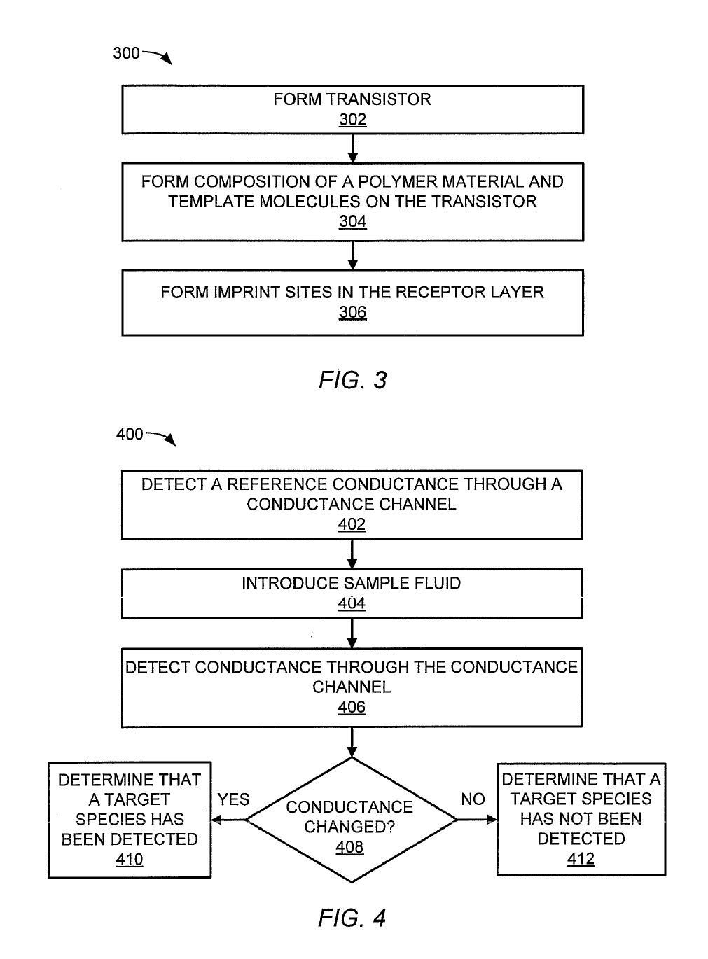

Turning now to FIG. 4, there is shown a flow diagram of a method of implementing a sensor 100, 150, 160 to determine whether a sample contains a target species, according to an example of the present disclosure. At block 402, a reference conductance level is detected through a conductance channel of the sensor 100, 150, 160. According to an example, a voltage is applied from an electrode positioned above the sensor 100, 150, 160 and through the receptor layer 114 and the transistor 116. In this example, the electrode from which the voltage is applied is positioned above the receptor layer 114, such that, a gap between an upper surface of the receptor layer 114 and the electrode is formed, as shown in FIG. 1D. In any regard, the conductance (or resistance) through the sensor 100, 150, 160 is detected through implementation of any suitable processes.

According to another example, the reference conductance level may be detected with charged template molecules positioned in the receptor layer 114. In this example, the reference conductance level comprises the conductance (or resistance) level at which a determination is made that target molecules have mated with the imprint sites 120a-120c. In addition, the target molecules are removed following performance of block 402.

At block 404, a sample fluid, liquid and/or gas, is introduced onto the receptor layer 114 of the sensor 100, 150, 160. The sample fluid comprises a fluid that is to be tested to determine whether the sample fluid contains a target molecule. More particularly, and as discussed above, the receptor layer 114 contains a plurality of imprint sites 120a-120c that are to mate with portions of particular target species or molecules. Thus, for instance, a first imprint site 120a may be at least one of shaped and chemically active to mate with a first portion of a target molecule and a second imprint site 120b may be at least one of shaped and chemically active to mate with a different portion of the target molecule. As such, when the sample fluid is introduced onto the receptor layer 114, if the molecules contained in the sample fluid comprise the target molecules, portions of the molecules are likely to mate with the imprint sites 120a-120c, similarly to a correct key fitting into a lock.

In various instances, confounding molecules may have portions that are able to mate with one of the imprint sites 120a-120c. However, because the receptor layer 114 includes a plurality of imprint sites 120a-120c that are to mate with different sections of target molecules, it is unlikely that confounding molecules will mate with each of the imprint sites 120a-120c.

At block 406, the conductance (or resistance) through a conductance channel in the sensor 100, 150, 160 is detected. The conductance (or resistance) is detected through application of a voltage across the sensor 100, 150 as discussed above.

At block 408, a determination as to whether the conductance (or resistance) has changed is made. In other words, a determination as to whether the conductance (or resistance) detected at block 406 differs from the reference conductance (or resistance) detected a block 402. If a determination that the conductance (or resistance) has changed is made at block 408, a determination that a target species has been detected by the sensor 100, 150, 160 is made, as indicated at block 410. However, if a determination that the conductance (or resistance) has not changed is made at block 408, a determination that a target species has not been detected by the sensor 100, 150, 160 is made, as indicated at block 412.

According to another example the reference conductance (or resistance) detected at block 402 was determined with charged template molecules contained in the receptor layer 114 as discussed above. In this example, at block 408, a determination as to whether the conductance (or resistance) detected at block 406 is equal to the reference conductance (or resistance) detected a block 402 is made. If a determination is made that the conductance (or resistance) is substantially equal to the reference conductance (or resistance) at block 408, an indication that a target species has been detected by the sensor 100, 150, 160 is made. However, if a determination is made that the conductance (or resistance) does not substantially equal the reference conductance (or resistance) at block 408, an indication that a target species has not been detected by the sensor 100, 150, 160 is made.

In one example, the conductance through the sensor 100, 150, 160 may change substantially only if all available imprint sites 120a-120c are filled with target species of at least one type. In this case, a specific combination of target species needs to be present to change the conductance. This additive approach is referred herein as an AND function. In this example, the current changes significantly only if target species of one AND another occupy most of the sites. In another example, the conductance through the sensor 100, 150, 160 may be sensitive to each different imprint site 120a-120c in a specific way and the conductance may then be utilized to describe the target species that are to mate with the different imprint sites 120a-120c. This approach is referred herein as an OR function. A significant change in current occurs when either one species OR another is present.

According to an example, following performance of the method 400, the surface of the receptor layer 114 is cleaned to remove the target species, if any, and any remaining species on the receptor layer 114. In this example, the sensor 100, 150 may be reused to detect the presence or absence of the target molecule in a different fluid sample.

In further examples, the method 400 is implemented on a plurality of sensors 100, 150, 160 of a sensor apparatus 200, 250. In one example, each of the sensors 100, 150, 160 comprises imprint sites 120a-120c that are shaped to receive portions of the same target molecules. In other examples, different ones of the sensors 100, 150, 160 comprise imprint sites 120a-120c that are shaped to receive portions of at least two different target molecules. In either of these examples, the sensors 100, 150, 160 of the sensor apparatus 200, 250, are matrix addressable. That is, the method 400 may be performed on each of the sensor 100, 150, 160 individually.

Although described specifically throughout the entirety of the instant disclosure, representative examples of the present disclosure have utility over a wide range of applications, and the above discussion is not intended and should not be construed to be limiting, but is offered as an illustrative discussion of aspects of the disclosure. Throughout the present disclosure, the terms “a” and “an” are intended to denote at least one of a particular element. As used herein, the term “includes” means includes but not limited to, the term “including” means including but not limited to.

What has been described and illustrated herein is an example along with some of its variations. The terms, descriptions and figures used herein are set forth by way of illustration only and are not meant as limitations. Many variations are possible within the spirit and scope of the subject matter, which is intended to be defined by the following claims—and their equivalents—in which all terms are meant in their broadest reasonable sense unless otherwise indicated.

What is claimed is:

1. A sensor comprising:
a transistor; and
a receptor layer positioned on the transistor, wherein the receptor layer comprises a plurality of imprint sites, wherein each of the plurality of imprint sites is to mate with a portion of a target molecular species, and wherein at least two of the plurality of imprint sites are to mate with different portions of the target molecular species.

2. The sensor according to claim 1, wherein the transistor comprises:
a gate electrode;
a source electrode;
a drain electrode;
a dielectric passivation layer positioned to electrically isolate the gate electrode from the source electrode and the drain electrode; and
a semiconductor layer positioned to electrically couple the source and drain.

3. The sensor according to claim 2, wherein a portion of the gate electrode is in contact with the receptor layer, and wherein the plurality of imprint sites are positioned directly above at least two of the source electrode, the drain electrode, and the gate electrode.

4. The sensor according to claim 2, further comprising a dielectric passivation layer, wherein the source electrode and the drain electrode are contained within the semiconductor layer, wherein the dielectric passivation layer is positioned between the semiconductor layer and the plurality of imprint sites, and wherein the plurality of imprint sites are positioned directly over the dielectric passivation layer.

5. The sensor according to claim 4, wherein the plurality of imprint sites are arranged in a two dimensional array in the receptor layer.

6. The sensor according to claim 5, wherein at least two of the plurality of imprint sites are at least one of shaped and chemically active to mate with portions of different target molecular species.

7. The sensor according to claim 5, wherein current applied through the array of imprint sites is to be at least one of logically ANDed and ORed.

8. The sensor according to claim 1, further comprising:
a top electrode spaced from the receptor layer to form a gap between the top electrode and the receptor layer, wherein the top electrode is to apply a voltage across the receptor layer and the transistor.

9. A sensor apparatus comprising:
a substrate; and
a plurality of sensors arranged in an array on the substrate, each of the plurality of sensors including:
a transistor; and
a receptor layer positioned on the transistor, wherein the receptor layer comprises a plurality of imprint sites, wherein each of the plurality of imprint sites is to mate with a portion of a target molecular species, and wherein at least two of the plurality of imprint sites is to mate with different portions of the target molecular species.

10. The sensor apparatus according to claim 9, wherein the plurality of imprint sites on a first one of the plurality of sensors are at least one of shaped and chemically active to mate with a first target molecular species and the plurality of imprint sites on a second one of the plurality of sensors are at least one of shaped and chemically active to mate with a second target molecular species.

11. The sensor apparatus according to claim 9, wherein the substrate comprises a flexible substrate and wherein the substrate is in a rolled configuration.

12. The sensor apparatus according to claim 9, wherein the plurality of sensors are matrix addressable.

13. A method of fabricating a sensor comprising:
forming a transistor;
forming a composition of a polymer material, template molecules, and functional monomers on the transistor to form a receptor layer, wherein the template molecules are the same type of molecules as a target molecular species; and
forming a plurality of imprint sites in the receptor layer, wherein each of the plurality of imprint sites is to mate with a portion of a target molecular species, and wherein at least two of the plurality of imprint sites are to mate with different portions of at the target molecular species.

14. The method according to claim 13, wherein the transistor comprises a gate electrode, a source electrode, a drain electrode, a gate dielectric layer positioned to electrically isolate the gate electrode from the source electrode and the drain electrode, and a semiconductor layer positioned to electrically isolate the gate electrode from the source electrode, and wherein forming the imprint sites further comprises forming the imprint sites in the receptor layer directly above at least two of the source electrode, the drain electrode, and the gate electrode.

15. The method according to claim 14, wherein the transistor comprises a gate electrode, a source electrode, a drain electrode, a gate dielectric layer positioned to electrically isolate the gate electrode from the source electrode and the drain electrode, and a semiconductor layer positioned to electrically isolate the gate electrode from the source electrode, and wherein forming the imprint sites further comprises forming the imprint sites in the receptor layer.

16. The method according to claim 14, wherein the transistor comprises a gate electrode, a source electrode, a drain electrode, a gate dielectric layer positioned to electrically isolate the gate electrode from the source electrode and the drain electrode, a semiconductor layer positioned to electrically couple the source and drain electrodes, and a dielectric passivation layer, wherein the source electrode and the drain electrode are contained within the semiconductor layer, wherein the dielectric passivation layer is positioned between the semiconductor layer and the plurality of imprint sites, and wherein forming the imprint sites further comprises forming the imprint sites in the receptor layer directly over the dielectric passivation layer.

17. The method according to claim 16, wherein forming the imprint sites in the receptor layer further comprises forming the imprint sites in a two dimensional array in the receptor layer.

18. A method of implementing a sensor having a transistor and a receptor layer having a plurality of imprint sites to mate with portions of a target molecular species, said method comprising:
detecting a reference conductance level through a conductance channel of the sensor;
introducing a sample fluid containing a plurality of molecular species, wherein the plurality of molecular species is to mate with the plurality of imprint sites if the plurality of molecular species comprise the target molecular species;
detecting a conductance through the conductance channel of the sensor;
determining whether the detected conductance differs from the detected reference conductance; and
determining that the target molecular species has either been detected or has not been detected in response to a determination as to whether the detected conductance differs from the detected reference conductance.

19. The method according to claim 18, wherein detecting a conductance through the conductance channel of the sensor further comprises:
applying a charging current across the sensor to charge a hold capacitor;
discharging the charge from the hold capacitor;
detecting a discharge rate of hold capacitor; and
wherein determining whether the detected conductance differs from the detected reference conductance further comprises determining whether the discharge rate of the hold capacitor differs from a detected reference discharge rate of the hold capacitor.
